(19) United States
(12) Patent Application Publication
(10) Pub. No.: US 2024/0304452 A1
(43) Pub. Date: Sep. 12, 2024

(54) SUBSTRATE PROCESSING METHOD AND SUBSTRATE PROCESSING APPARATUS

(71) Applicant: Tokyo Electron Limited, Minato-ku, Tokyo (JP)

(72) Inventors: Tsunemoto OGATA, Koshi-shi, Kumamoto (JP); Suguen LEE, Koshi-shi, Kumamoto (JP); Hiroshi MARUMOTO, Koshi-shi, Kumamoto (JP)

(21) Appl. No.: 18/701,058

(22) PCT Filed: Oct. 12, 2022
(86) PCT No.: PCT/JP2022/038040

§ 371 Date: Apr. 12, 2024

(30) Foreign Application Priority Data
Oct. 19, 2021 (JP) 2021-171136

(51) Int. Cl. H01L 21/306; H01L 21/67

(52) U.S. Cl. CPC H01L 21/30604; H01L 21/6708

(57) ABSTRACT

A substrate processing method including a first etching process of performing etching, where a first process liquid paddle is formed on an entire surface of a substrate, by locally discharging a second process liquid from a nozzle toward a target area locally set on the substrate surface, such that an etching rate in the target area differs from that in other areas; and a second etching process of etching the entire surface of the substrate simultaneously by supplying an etching liquid so that the entire surface of the substrate is covered with a liquid film of the etching liquid while rotating the substrate, wherein one of the first and second process liquids used in the first etching process is the etching liquid, and the other is an etching inhibitor liquid that lowers an etching rate of the substrate surface by the etching liquid when mixed with the etching liquid.

### TECHNICAL FIELD

The present disclosure relates to a substrate processing method and a substrate processing apparatus.

### BACKGROUND

In the manufacture of semiconductor devices, wet etching is performed to remove a film formed on a surface of a substrate such as a semiconductor wafer using a chemical liquid. In recent years, there has been a demand for higher in-plane uniformity of etching amount. Patent Document 1 discloses a technique for enhancing in-plane uniformity of etching amount in a substrate processing apparatus that supplies an etching liquid to a central portion of a rotating substrate to perform a wet etching on the substrate while spraying a temperature adjustment gas to a peripheral portion of the substrate which is easily cooled.

### PRIOR ART DOCUMENT

### Patent Document

Patent Document 1: Japanese Patent Laid-Open Publication No. 2001-085383

The present disclosure provides a technique for locally controlling an etching amount when etching a surface of a substrate.

### SUMMARY

According to one embodiment of the present disclosure, there is provided a substrate processing method including a first etching process of performing etching, in a state where a paddle of a first process liquid is formed on an entire surface of a substrate, by locally discharging a second process liquid from a nozzle toward a target area locally set on the surface of the substrate, such that an etching rate in the target area differs from an etching rate in other areas; and a second etching process of etching the entire surface of the substrate simultaneously by supplying an etching liquid so that the entire surface of the substrate is covered with a liquid film of the etching liquid while rotating the substrate, wherein one of the first process liquid and the second process liquid used in the first etching process is the etching liquid, and the other is an etching inhibitor liquid that lowers an etching rate of the surface of the substrate by the etching liquid when mixed with the etching liquid.

According to the present disclosure, it is possible to locally control an etching amount when etching a surface of a substrate.

### BRIEF DESCRIPTION OF DRAWINGS

FIG. 1 is a schematic cross-sectional view of a substrate processing system according to one embodiment of a substrate processing apparatus.

FIG. 2 is a schematic longitudinal-sectional view illustrating a configuration of a process unit of the substrate processing system in FIG. 1.

FIGS. 3A to 3E are operational diagrams illustrating an etching method according to a first embodiment of a substrate processing method.

FIGS. 4A to 4E are operational diagrams illustrating an etching method according to a second embodiment of a substrate processing method.

FIGS. 5A to 5E are operational diagrams illustrating an etching method according to a third embodiment of a substrate processing method.

FIGS. 6A to 6E are operational diagrams illustrating an etching method according to a fourth embodiment of a substrate processing method.

FIG. 7 is a graph illustrating a concept of setting a process condition of a first etching process.

FIG. 8 is a graph illustrating experimental results obtained by investigating an etching amount distribution in the first etching process.

FIG. 9 is an operational diagram illustrating a first modification of a second etching process.

FIG. 10 is an operational diagram illustrating a second modification of the second etching process.

### DETAILED DESCRIPTION

One embodiment of a substrate processing apparatus will be described with reference to the accompanying drawings.

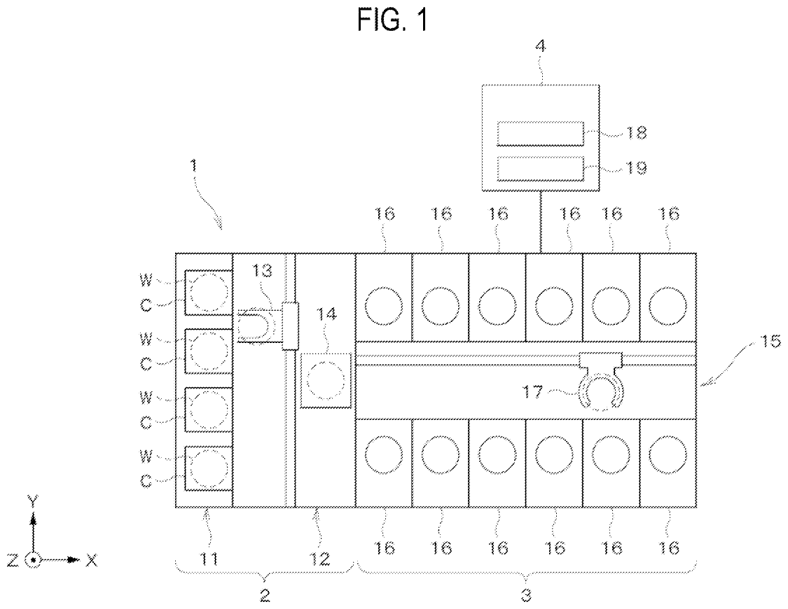

FIG. 1 is a diagram illustrating a schematic configuration of a substrate processing system according to the present embodiment. In the following, an X-axis, a Y-axis, and a Z-axis, which are orthogonal to each other, are defined to clarify positional relationships, with the Z-axis positive direction representing the vertical upward direction.

As illustrated in FIG. 1, the substrate processing system 1 includes a loading/unloading station 2 and a process station 3. The loading/unloading station 2 and the process station 3 are provided adjacent to each other.

The loading/unloading station 2 includes a carrier placing section 11 and a transfer section 12. In the carrier placing section 11, a plurality of carriers C that accommodates a plurality of substrates, i.e., substrates W such as semiconductor wafers in the present embodiment, in a horizontal state are placed.

The transfer section 12 is provided adjacent to the carrier placing section 11 and includes a substrate transfer device 13 and a deliverer 14 therein. The substrate transfer device 13 includes a substrate holding mechanism that holds the substrate W. Further, the substrate transfer device 13 is capable of moving in both the horizontal and vertical directions as well as pivoting around a vertical axis, and serves to transfer the substrate W between the carrier C and the deliverer 14 using the substrate holding mechanism.

The process station 3 is provided adjacent to the transfer section 12. The process station 3 includes a transfer section 15 and a plurality of process units 16. The plurality of process units 16 is provided side by side at both sides of the transfer section 15.

The transfer section 15 includes a substrate transfer device 17 therein. The substrate transfer device 17 includes a substrate holding mechanism that holds the substrate W. Further, the substrate transfer device 17 is capable of moving in both the horizontal and vertical directions as well as pivoting around a vertical axis, and serves to transfer the substrate W between the deliverer 14 and the process units 16 using the substrate holding mechanism.

Each process unit 16 performs a predetermined substrate processing on the substrate W transferred by the substrate transfer device 17.

Further, the substrate processing system 1 includes a control device 4. The control device 4 is, for example, a computer and includes a controller 18 and a storage 19. The storage 19 stores programs that control various processes executed in the substrate processing system 1. The controller 18 controls the operation of the substrate processing system 1 by reading and executing the programs stored in the storage 19.

In addition, the programs may be recorded on a computer readable storage medium, and may be installed from the storage medium into the storage 19 of the control device 4. Examples of the computer readable storage medium include a hard disk (HD), flexible disk (FD), compact disk (CD), magneto-optical disk (MO), memory card, etc.

In the substrate processing system 1 configured as described above, first, the substrate transfer device 13 of the loading/unloading station 2 retrieves the substrate W from the carrier C placed on the carrier placing section 11, and then places the retrieved substrate W onto the deliverer 14. The substrate W placed on the deliverer 14 is then retrieved from the deliverer 14 by the substrate transfer device 17 of the process station 3 and is loaded into the process unit 16.

The substrate W loaded into the process unit 16 is processed by the process unit 16, and is then unloaded from the process unit 16 by the substrate transfer device 17, thus being placed onto the deliverer 14. Then, the processed substrate W placed on the deliverer 14 is returned to the carrier C in the carrier placing section 11 by the substrate transfer device 13.

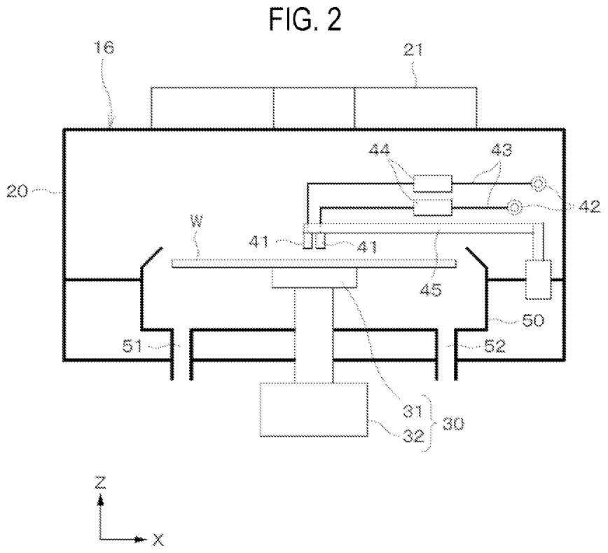

Next, a configuration of the process unit 16 will be described with reference to FIG. 2.

The process unit 16 has a chamber 20 defining a process space. A fan filter unit (FFU) 21 is provided on a ceiling of the chamber 20. The FFU 21 ejects a clean gas downward into the chamber 20.

The process unit 16 is provided with a spin chuck (substrate holding rotation mechanism) 30. The spin chuck 30 includes a substrate holder (chuck) 31 that holds the substrate W in a horizontal posture and a rotation drive 32 that rotates the substrate W held by the substrate holder around a vertical axis.

The substrate holder 31 may be of a type called a mechanical chuck that mechanically holds a peripheral portion of the substrate W using a holding member such as a gripping claw, or may be of a type called a vacuum chuck that vacuum-suctions a central portion of a back surface of the substrate W. The rotation drive 32 may be configured, for example, with an electric motor.

The process unit 16 is provided with a process fluid supply 40 for supplying various process fluids necessary for the processing of the substrate W to the substrate W.

The process fluid supply 40 includes a plurality of nozzles 41 (only two are illustrated in FIG. 2) that discharge the process fluids toward the substrate W. In one embodiment, the process fluids supplied to the substrate W in the process unit 16 include a process liquid and a process gas. Examples of the process liquid include dilute hydrofluoric acid (DHF), deionized water (DIW), and isopropyl alcohol (IPA). An example of the process gas is a nitrogen gas (N₂ gas). The process fluids are not limited to those described above but may be selected and used as needed from a variety of known process fluids used in a single wafer type substrate processing unit for wet etching in the technical field of semiconductor manufacture.

In one embodiment, different process fluids are discharged from different nozzles 41, respectively. In this case, a necessary process fluid is supplied to each nozzle 41 from a process fluid source 42 through a supply line 43, which is provided with a supply controller 44 as schematically illustrated by the white-outlined box in FIG. 2. The process fluid source 42 is, for example, a tank storing the process fluids, or plant equipment. The supply controller 44 is constituted with an opening/closing valve, a flow meter, a flow control valve, etc. In another embodiment, a single nozzle may selectively discharge multiple types of process fluids (e.g., DHIF and DIW) as needed.

One of a plurality of nozzles 41 may be a two-fluid nozzle (two-fluid spray nozzle). As is well-known in the art, a two-fluid nozzle is configured to generate and discharge a mist-like mixture fluid of process liquid and process gas by merging a flow of process gas (e.g., nitrogen gas) supplied from a process gas source with a process liquid (e.g., DHF or DIW) supplied from a process liquid source.

One of the plurality of nozzles 41 may be a mono-fluid spray nozzle. The mono-fluid spray nozzle discharges only a liquid in a mist form.

The plurality of nozzles 41 is carried on one or more nozzle arms 45 (only one is illustrated in FIG. 2). The nozzle arm 45 is configured to position each nozzle 41 at any position (radial position) between a position above a central portion of the substrate W held by the substrate holder 31 and a position above the peripheral portion of the substrate W. The nozzle arm may be of a type capable of pivoting around a vertical axis, or may be of a type capable of translating along a guide rail.

A liquid receiving cup 50 is provided around the substrate holder to collect the process liquid scattered from the rotating substrate W. The process liquid collected by the liquid receiving cup 50 is discharged to the outside of the process unit 16 through a liquid drain port 51 provided at the bottom of the liquid receiving cup 50. An exhaust port 52 is also provided at the bottom of the liquid receiving cup 50, and the interior of the liquid receiving cup 50 is suctioned through the exhaust port 52.

Several embodiments of an etching method will be described below. In addition, in the following embodiments, deionized water (DIW), dilute hydrofluoric acid (DHF), isopropyl alcohol (IPA), etc. are discharged as the process liquid from the nozzles. DIW is used as a pre-wet liquid, paddle-forming liquid, rinse liquid, etc. DHF is used as an etching liquid. IPA is used as a drying liquid and/or as a paddle-forming liquid.

Instead of DHF, for example, SC1 or sulfuric acid peroxide (SPM) may be used as the etching liquid (although not limited to these). Functional water may be used instead of DIW as the pre-wet liquid, paddle-forming liquid, or rinse liquid. The functional water refers to DIW with a small amount of solute (such as ammonia, carbon dioxide, etc.) dissolved therein to impart a special function (e.g., conductivity) that DIW alone does not possess.

In the following description, each nozzle 41 will be referred to as the “name of the process liquid that the nozzle is discharging or about to discharge”+“nozzle.” In other words, for example, a nozzle that discharges DIW will also be called a DIW nozzle.

In the practical apparatus operation, there are often cases where two or more types of process liquids (e.g., DIW and DHF) are selectively discharged from one common nozzle 41, but that nozzle will be referred to as the “name of the process liquid that is being discharged or about to be discharged at that time”+“nozzle.” In other words, for example, one nozzle 41 may be called a “DIW nozzle” at one time and a “DHF nozzle” at another time.

Further, there is a two-fluid nozzle that functions both as a mono-fluid nozzle and as a two-fluid nozzle. In other words, for example, when supplying only the process liquid (e.g., DHF) without supplying a gas (e.g., N₂ gas) to a two-fluid nozzle, the two-fluid nozzle acts as a mono-fluid nozzle, and when supplying both the gas and the process fluid to a two-fluid nozzle, the two-fluid nozzle acts to discharge a mixture fluid (two fluids) of mist-like process fluid and gas. Regardless of whether a nozzle is dedicated to mono-fluid discharge or two-fluid discharge or used for both, the nozzle will be referred to as the “name of the process liquid that is being discharged or about to be discharged at that time”+“nozzle.” In other words, for example, one nozzle may be called a “DHF mono-fluid nozzle” at one time and a “DHF two-fluid nozzle” at another time. The “DHF mono-fluid nozzle” may also be referred to simply as “DHF nozzle” by omitting “mono-fluid.”

### First Embodiment of Etching Method

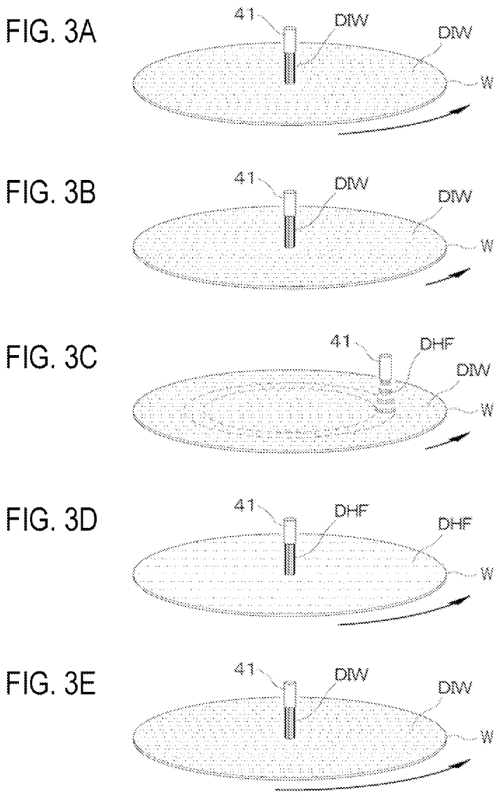

A first embodiment of an etching method will be described with reference to FIGS. 3A to 3E. In addition, reference numeral 41 is given to all nozzles, but this does not mean that they are all the same nozzle.

### <Pre-wet Process>

The spin chuck 30 holds the substrate W in a horizontal posture and rotates it at a first rotational speed (e.g., a relatively high rotational speed of about 1,000 rpm) around a vertical axis. In this state, DIW is supplied from a DIW nozzle to a central portion of a surface of the substrate W at a first flow rate (e.g., a relatively large flow rate of about 1.5 L/min). The DIW applied on a central portion of the surface of the substrate W flows toward the periphery of the substrate W due to a centrifugal force, spreading as it flows. This allows the entire surface of the substrate W to be covered with a liquid film of DIW (FIG. 3A).

In addition, the “central portion of the substrate W” refers to a position of the rotation center of the substrate W or a position in the vicinity of the rotation center. Here, the “position in the vicinity of the rotation center of the substrate” refers to a position close to the rotation center of the substrate such that when a process liquid (here, DIW) is applied at that position from a nozzle (here, DIW nozzle), the surface of the substrate at the rotation center is covered with the process liquid spreading with the momentum of the liquid application immediately after the application.

### <Paddle-Forming Process>

When a first time (e.g., about 10 seconds) has passed from the start of the pre-wet process in a state where the DIW continues to be discharged at the first flow rate from the DIW nozzle, the rotational speed of the substrate W is significantly reduced to a second rotational speed (e.g., an extremely low rotational speed of about 10 rpm). This allows the entire surface of the substrate W to be covered with a relatively thick liquid film of DIW (DIW paddle) (FIG. 3B).

<First Etching Process (Localized etching Process)>

After a second time (e.g., about 5 seconds) has passed from the start of the paddle-forming process, the discharge of DIW from the DIW nozzle is stopped and the substrate W continues to be rotated at the second rotational speed. In this state, DHF is discharged to the substrate W from a DHIF nozzle. The DHIF nozzle used here may be, for example, a two-fluid nozzle that discharges a mixture fluid of DHF mist and nitrogen gas.

When the DHF nozzle used in the first etching process is a two-fluid nozzle, DHF (etching liquid) is supplied to the two-fluid DHF nozzle at a flow rate of, e.g., about 10 to 200 ml/min, and a nitrogen gas (inert gas) is also supplied at a pressure of about 10 to 100 Pa.

At this time, the DHF nozzle is positioned above a predetermined radial position on the substrate where DHF is applied (this position may be represented as a distance R from the rotation center of the substrate). Since the substrate W rotates at the second rotational speed, DHF discharged from the DHF nozzle is applied on the DIW paddle to scan the substrate W (i.e., the DIW paddle) along a circle of radius R (see FIG. 3C).

The DHF applied on the DIW paddle causes the DIW paddle to be recessed in the vicinity of the liquid application point and diffuses around the liquid application point while being diluted by DIW constituting the paddle. Therefore, a ring-shaped area (target area) enclosed by a circle of radius R-ΔR1 and a circle of radius R+ΔR2 on the surface of the substrate W is etched locally in a small amount. Areas other than the target area are either not etched at all or etched minimally. In addition, if the rotational speed of the substrate W is extremely low, for example, about 10 rpm, ΔR1 and ΔR2 may be considered to be approximately equal.

Assuming that the substrate W is rotating at the rotational speed of 10 rpm as described above, when DHF is discharged from the DHF nozzle for exactly 6 seconds, the application of DHF is made on the entire ring-shaped area described above. In other words, the liquid application point completes a circular-travel around the ring-shaped area. This allows the ring-shaped area to be etched approximately uniformly in a small amount (e.g., a few angstroms).

In addition, strictly speaking, the etching amount is the greatest in the vicinity of a position where DHF is first applied, and is relatively reduced in the vicinity of a position where DHF is later applied. However, this level of variation in etching amount is not practically problematic (details will be described later).

The first DHF nozzle 41 may be carried on the first nozzle arm 45, and the second DHF nozzle 41 may be carried on the second nozzle arm 45, so that the liquid application point of DHF from the first DHF nozzle and the liquid application point of DHF from the second DHF nozzle may both be positioned on the circumference of radius R at opposite positions in the radial direction of the substrate W. This may reduce a variation in etching amount in the circumferential direction.

As will be described in detail later, in the first embodiment, the first etching process is used to etch an area where the etching amount becomes inevitably smaller in a second etching process, where process conditions are set to enhance the in-plane uniformity of etching amount as much as possible.

### <Second Etching Process (Overall Etching Process)>

After completion of the first etching process (localized etching process), DHF (DHF as a mono-fluid) is discharged from the DHF nozzle onto the central portion of the substrate W, and at the same time, the rotational speed of the substrate W is increased to a third rotational speed (e.g., 1,000 rpm). This replaces DIW covering the surface of the substrate W (somewhat mixed with DHF in the first etching process) with DHIF. Continuing this state for a third time (e.g., about 30 seconds) results in the etching of the surface of the substrate W (FIG. 3D).

Transition from the first etching process to the second etching process may be made, for example, as follows. In a case where two-fluid DHF is discharged from a two-fluid nozzle that is also usable as a mono-fluid nozzle in the first etching process, the two-fluid nozzle is moved to a space above the central portion of the surface of the substrate W after completion of the first etching process, and the supply of nitrogen gas to the two-fluid nozzle is stopped, while the discharge flow rate of DHF is increased.

Different DHF nozzles may be used in the first and second etching processes. In other words, the DHF nozzle, which has stopped the discharge of DHF, may be retracted from a space above the substrate after completion of the first etching process, and DHF may be supplied to the substrate from another DHF nozzle positioned above the central portion of the substrate to perform the second etching process.

### <Rinse Process>

Once the second etching process (overall etching process) has been executed for a predetermined time, the discharge of DHF from the DHF nozzle is stopped, and DIW is discharged from the DIW nozzle onto the central portion of the surface of the substrate W. Further, the rotational speed of the substrate W may be preferably further increased to a fourth rotational speed (e.g., 1,500 rpm). This helps DIW to wash away DHF and etching-by-products from the surface of the substrate W (FIG. 3E).

### <Drying Process>

Next, a drying process is performed to dry the substrate W. In this drying process, various known drying methods may be used. For example, in a first method, the discharge of DIW from the DIW nozzle may be stopped while continuing to rotate the substrate W from the end of the rinse process, and then spin drying may be performed. In a second method, DIW on the surface of the substrate W may be replaced with IPA to form an IPA paddle, and then supercritical drying may be performed. In a third method, a two-step drying process may be performed, including an IPA replacement step and a subsequent N₂ gas drying step. In the IPA replacement step, the discharge of DIW from the DIW nozzle is stopped while continuing to rotate the substrate W from the end of the rinse process, and IPA is discharged from an IPA nozzle onto the surface of the substrate W to replace DIW on the surface of the substrate W with IPA. In the N₂ gas drying step, a N₂ gas is sprayed onto the substrate W from a N₂ nozzle while moving a N₂ gas spraying position toward the periphery of the substrate W to expand a drying core, resulting in the drying of the substrate W. In the N₂ gas drying step, IPA may be discharged from the IPA nozzle while the N₂ gas is discharged from the N₂ nozzle. In this case, the IPA nozzle and the N₂ nozzle are moved radially outward while maintaining a positional relationship that the radial position of the liquid application point of IPA on the substrate W is consistently radially outside the radial position of an impact point of the N₂ gas on the substrate W. Similar drying methods may be appropriately selected and used in each of embodiments described later.

According to the first embodiment of the etching method described above, even if the second etching process (overall etching process) alone does not provide sufficient in-plane uniformity of etching amount, it is possible to enhance the in-plane uniformity of etching amount by performing the first etching process (localized etching process). In addition, in many cases, the etching amount at the same radial position in the second etching process (i.e., the etching amount within a ring-shaped area with a narrow radial width) is approximately the same across the entire circumferential direction, and a variation in etching amount appears along the radial direction. Therefore, it is possible to enhance the in-plane uniformity of etching amount by combining the first and second etching processes described above.

In the second etching process, if there are two or more ring-shaped areas (areas with different radii) having relatively small etching amounts compared to other areas, the first etching process may be performed two or more times. In this case, after completion of the first etching process, the DIW rinse process, the paddle-forming process, and the second iteration of the first etching process may be executed sequentially. If there are a plurality of DIF nozzles (DIF two-fluid nozzles) carried on separate nozzle arms, it is also possible to simultaneously perform the first etching process for two or more ring-shaped areas.

In a case where an etching target film becomes locally thicker due to process conditions or other factors in a previous process (e.g., film formation process), the above first embodiment is also beneficial for correcting the uneven film thickness.

The purpose of performing the first etching process is not limited to enhancing the in-plane uniformity of etching amount but may also be to form an area with a locally large (small) etching amount on a single substrate.

### Second Embodiment of Etching Method

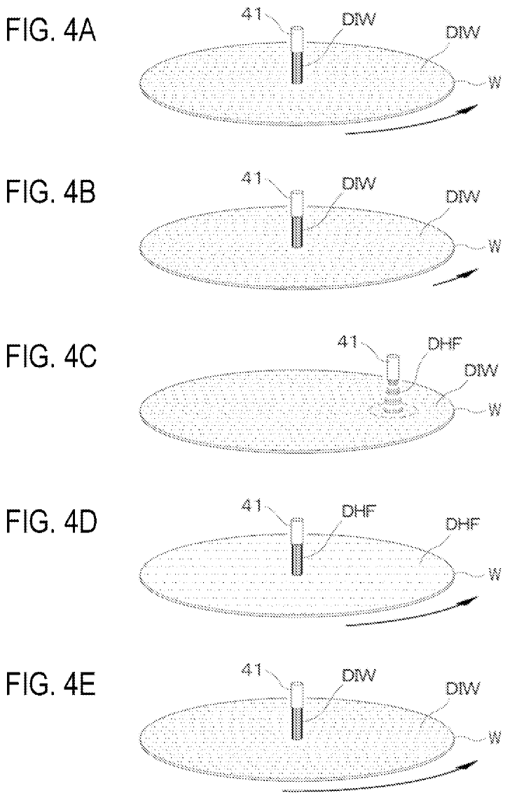

A second embodiment of an etching method will be described with reference to FIGS. 4A to 4E. The second embodiment differs from the first embodiment only in the first etching process (FIG. 4B), while the other processes, i.e., the pre-wet process in FIG. 4A, the second etching process in FIG. 4C, the rinse process in FIG. 4D, and the drying process (not illustrated) remain all the same. In the first etching process of the second embodiment, the rotation of the substrate W is stopped, and DHF is discharged from the DHF nozzle to ensure that DHF is applied at a desired position on the surface of the substrate W where the DIW paddle is located. This allows an approximately circular area (target area) where DHF diffuses around the liquid application point of DHF to be etched in a small amount.

This second embodiment may be applied in a case where areas with lower etching amounts locally occur not in a ring shape, but at specific circumferential positions in the second etching process (overall etching process). Further, in a case where an etching target film becomes locally thicker due to process conditions or other factors in a previous process (e.g., film formation process), it is also beneficial for correcting the uneven film thickness.

In the second embodiment as well, the first etching process may be performed two or more times.

The first etching process according to the first embodiment and the first etching process according to the second embodiment may be combined. Specifically, for example, the rinse process and the paddle-forming process may be performed after completion of the first etching process according to the first embodiment, and then the first etching process according to the second embodiment may be performed.

In the above first and second embodiments, the first etching process is performed first, followed by the second etching process, but the order of these processes may be reversed. The order in this case will be briefly described. First, the pre-wet process with DIW is performed, and then the second etching process is performed, followed by the rinse process with DIW, the paddle-forming process, the first etching process, the rinse process with DIW, and finally the drying process. It is possible to arbitrarily select whether to perform the first etching process or the second etching process first by taking factors such as the process throughput into consideration. However, if the surface of the substrate changes from hydrophilic to hydrophobic by the second etching process, the first etching process may be performed first since it becomes difficult to stably form the DIW paddle after the second etching process.

### Third Embodiment of Etching Method

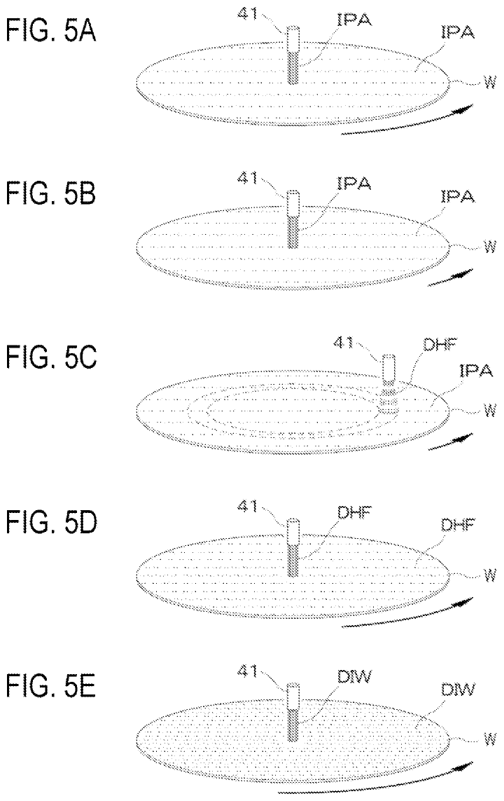

A third embodiment of an etching method will be described with reference to FIGS. 5A to 5E. The third embodiment differs from the first embodiment in that IPA is used instead of DIW in the pre-wet process (FIG. 5A) and the paddle-forming process (FIG. 5B) and that DHF is supplied to the IPA paddle in the first etching process (FIG. 5C) (localized etching process). The other processes (the rinse process in FIG. 5D and the drying process (not illustrated)) remain all the same.

When the surface of the substrate W is hydrophobic (having a large contact angle), it may not be possible to form a paddle covering the entire surface of the substrate W using DIW which has high surface tension, or even if formed, the paddle may not be stable. In this case, using IPA which has low surface tension allows the formation of a paddle covering the entire surface of the substrate W.

The paddle may be formed using a mixture liquid of IPA and DIW. The surface tension of the mixture liquid increases with a higher content of DIW, but it is not always necessary to have as low surface tension as pure IPA in forming a paddle. In this case, diluting IPA with DIW to an extent that does not cause problems for paddle formation may reduce the amount of expensive IPA used, thereby lowering the running costs of the apparatus.

It is possible to use other suitable low surface tension liquids (liquids with a lower surface tension than DIW) instead of IPA. However, it is desirable that the low surface tension liquid be compatible with the etching liquid and not inhibit a reaction between the etching liquid and the surface of the substrate W.

In the third embodiment, since stable paddle formation is possible even when an etching target surface is hydrophobic, it is possible to arbitrarily select whether to perform the first etching process or the second etching process first by taking factors such as the process throughput into consideration.

### Fourth Embodiment of Etching Method

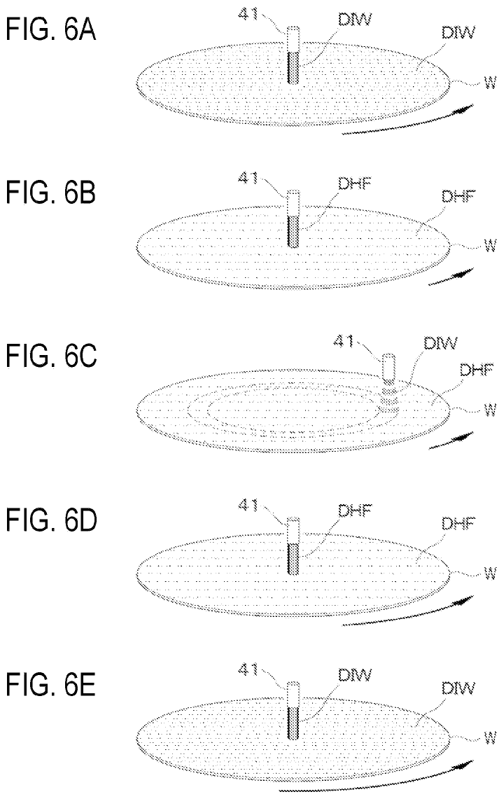

A fourth embodiment of an etching method will be described with reference to FIGS. 6A to 6E. The fourth embodiment differs from the first embodiment in that a paddle is formed using the etching liquid (DHF) in the paddle-forming process (FIG. 6B) and DIW is discharged from the nozzle to the etching liquid paddle in the first etching process (localized etching process) in FIG. 6C. The other processes (the pre-wet process by DIW in FIG. 6A, the rinse process in FIG. 6D, and the drying process (not illustrated)) remain all the same.

In the first etching process of the first embodiment described above, only a partial area (target area) of the surface of the substrate W is locally etched by discharging DHIF from the DHIF nozzle to the DIW paddle. On the other hand, in the first etching process of the fourth embodiment, DIW is discharged from the DIW nozzle to a DHIF paddle, thereby diluting DHIF with DIW within a partial area (target area) of the surface of the substrate W and locally suppressing etching in that area.

In addition, similar to the second embodiment of the etching method described above, the first etching process may be performed such that the rotation of the substrate W is stopped and DIW is discharged from the DIW nozzle such that DIW is applied at a desired position of the DIW paddle on the surface of the substrate W. In so doing, etching within an approximately circular area centered on the liquid application point is locally suppressed.

In addition, there may be a case where the etching rate increases due to dilution with DIW depending on the concentration of DHF supplied from the DHF nozzle (this is due to a change in the ionization state). Therefore, the fourth embodiment may also be used as a method to locally promote etching in a target area.

### [Determination of Conditions of First Etching Process (Localized Etching Process)]

Determination of conditions of the first etching process (localized etching process) according to the first to fourth embodiments will be described below.

The first embodiment will be described by way of example. First, under the same conditions as in the first embodiment, the pre-wet process, the second etching process (overall etching process), the rinse process, and the drying process are sequentially performed to realize a substrate processing (hereinafter referred to as “normal processing” for simplicity). In the normal processing, the paddle-forming process and the first etching process (localized etching process) are not performed. Conditions for this normal processing (particularly the second etching process) are determined based on previous methods (trial and error through a preliminary test, etc.) to enhance the in-plane uniformity of etching amount as high as possible.

For the substrate that has undergone the above normal processing, the distribution of etching amount is measured using a known non-destructive inspection method (e.g., spectroscopic ellipsometry). Specifically, for example, measurement points are equidistantly set (e.g., at an interval of about 5 mm) depending on the diameter of the substrate, and the etching amount at each measurement point is measured. In addition, the measurement points may be set along a radius (i.e., on a line connecting the center to one point on the periphery), may be set along two radially extending straight lines orthogonal to each other, or may be set along four radially extending straight lines in a relationship rotated by 45 degrees.

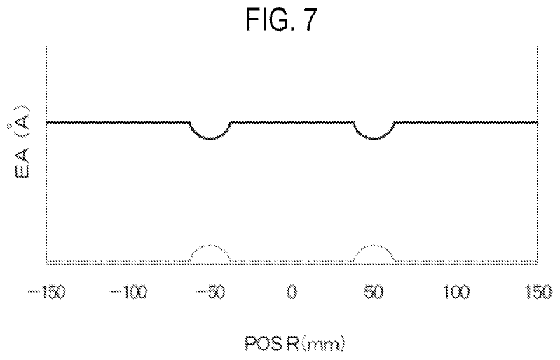

A graph of FIG. 7 illustrates an example of the etching amount distribution measured along the diameter of the substrate with a solid line in a greatly simplified manner. The vertical axis of the graph represents the etching amount EA and the horizontal axis represents the radial position (POS) (unit: mm) of each measurement point with the position of the substrate center set as ±0 mm. In the example illustrated in the graph of FIG. 7, the etching amount is reduced by a few Å (angstroms) in a ring-shaped area around a distance of about 50 mm from the center of the substrate. In the other areas, the target etching amount is approximately achieved, and the etching amount is also roughly uniform.

If the etching amount distribution in the second etching process is obtained as illustrated by the solid line in the graph of FIG. 7, by executing the first etching process under conditions in which results of the etching amount distribution indicated by a dashed line in the graph of FIG. 7 is obtained, an etching with high in-plane uniformity can be achieved through the first and second etching process.

The conditions of the first etching process may be determined through a preliminary test. Parameters for determining the conditions of the first etching process may include an etching time, a type of liquid used to form a paddle, a paddle thickness, a rotational speed of the substrate, a flow rate of the etching liquid from the nozzle (including a gas flow rate in a case of two-fluid discharge), a discharge form of the etching liquid from the nozzle, etc.

The conditions of the first etching process are arbitrary as long as a desired etching amount distribution is realized, but may be determined based on the following considerations.

The rotational speed of the substrate may be preferably low, specifically 100 rpm or less, and more preferably 30 rpm or less. At a higher substrate rotational speed, a liquid (DIW) forming a paddle may flow and an etching liquid (DHF) applied on the paddle may not stay in place, leading to the etching of an unintended area. In one appropriate embodiment, the rotational speed of the substrate is set to 10 rpm. At such a low rotational speed, the flow of the liquid forming the paddle occurs only negligibly, so that the etching liquid applied on the paddle spreads into the paddle due to mutual diffusion between the etching liquid (DHF) and the paddle liquid (DIW) and stirring effects during application. When the etching liquid is discharged in a two-fluid state, the stirring effects are enhanced (see also test results as described later).

The number of rotations of the substrate (which corresponds to the process time if the rotational speed is fixed) may also preferably be as low as possible. Increasing the number of rotations may cause the etching liquid to spread to positions away from the liquid application point, leading to the etching of an unintended area. In the above appropriate example with the substrate rotational speed of 10 rpm, the number of rotations of the substrate is set to 1 (meaning that the time of the first etching process is 6 seconds).

Once the rotational speed and number of rotations (process time) of the substrate are determined, for example, as described above (although not limited to the above conditions), the discharge form and discharge flow rate of the etching liquid from the nozzle (including the gas flow rate in a case of two-fluid discharge) may be determined.

The discharge form of the etching liquid may be classified into a liquid column form or a spray (droplet) form. The spray form may be classified into a mono-fluid form (simply spraying the etching liquid as droplets) or two-fluid form (spraying a mixture fluid of etching liquid droplets and inert gas). When the etching liquid is discharged in the form of droplets, the spray angle is also taken into consideration.

Increasing the spray angle allows for localized etching over a relatively wide radial range, while decreasing the spray angle allows for localized etching over a relatively narrow radial range. Discharging the etching liquid in a form of a fine liquid column (mono-fluid) allows for localized etching over a relatively narrow radial range.

As described above, the etching liquid may be discharged in either a two-fluid form or a mono-fluid form. Experimental results indicate that when the etching liquid is discharged in a two-fluid form, the radial width of localized etching is wide and the in-plane uniformity and inter-plane uniformity of etching amount are high, compared to a mono-fluid form (details are described later). Therefore, except for a case where etching a particularly narrow radial area is desired, the etching liquid may be discharged in a two-fluid form.

For example, when discharging the etching liquid (e.g., DHF) using a two-fluid nozzle, a test may be performed using parameters such as the spray angle of the two-fluid nozzle, the flow rate of the etching liquid, the gas flow rate, etc., to find the discharge conditions of the etching liquid where an appropriate etching area width is stably achieved. In addition, it is generally desirable for two fluids discharged from a two-fluid nozzle to collide with a paddle with a force sufficient to cause the surface of the paddle to be slightly recessed (although not limited to this).

It is clear that those skilled in the art who read the present disclosure can easily find the process conditions of the first etching process capable of etching a desired radial area with a desired etching amount by conducting the test while considering the above-described factors and changing various parameter values.

### [Test on First Etching Process]

A test was conducted to confirm the etching amount distribution when the first etching process was performed alone. A bare silicon wafer with an oxide film formed by thermal CVD was prepared as an etching target substrate. For this substrate, DHIF was supplied for 6 seconds from a nozzle to a position 100 mm away from the center of the substrate while rotating the substrate with a DIW paddle formed thereon at a rotational speed of 10 rpm. The discharge flow rate of DHF from the nozzle was 100 ml/min in both cases of mono-fluid discharge and two-fluid discharge. In the case of two-fluid discharge, a pressure of 10 kPa was applied to the nozzle and a nitrogen gas was supplied. Four substrates were processed for each of mono-fluid and two-fluid processes. The processed substrate was subjected to film thickness measurements using spectroscopic ellipsometry to obtain the etching amount distribution.

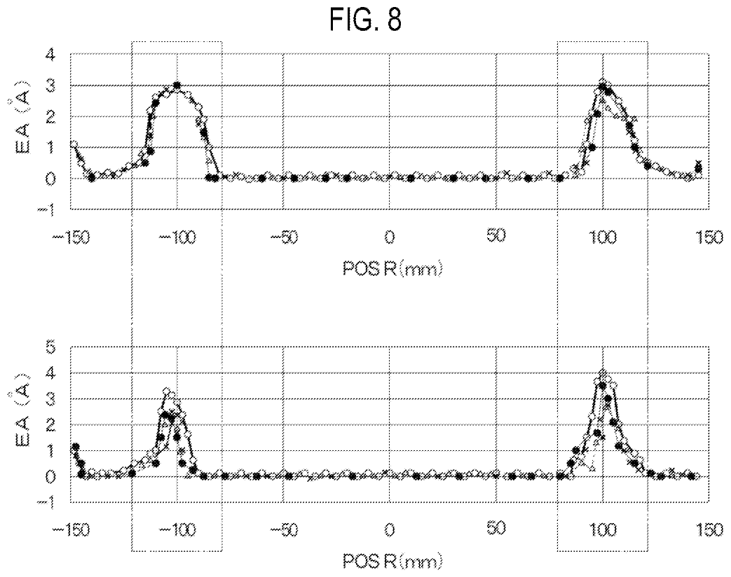

The test results are illustrated in a graph of FIG. 8. The upper section of the graph illustrates the results when two-fluid discharge was performed, while the upper section illustrates the results when mono-fluid discharge was performed. The horizontal axis of the graph represents the distance (unit: mm) of each measurement point from the center of the substrate, with positive values representing measurement points at the right of the center of the substrate and negative values representing measurement points at the left. The vertical axis of the graph represents the etching amount (unit: A).

It is visually understandable from the graph of FIG. 8 that the two-fluid process results in a wider radial width of etching and higher stability in etching amount across the wafers.

Further, a variation in etching amount was confirmed based on the acquired data. The results are illustrated in Tables 1 and 2 below. In these tables, for example, the area “−100±10” indicates that data acquired within the area from a −90 mm position to a −110 mm position was processed when targeting a −100 mm position for the two-fluid (or mono-fluid) discharge. Regardless of the area width, conditions for each of the two-fluid discharge and mono-fluid discharge were identical. σ indicates the standard deviation of all etching amounts obtained within the corresponding area for the four substrates.

TABLE 1

| Area (mm) | σ (two-fluids) | σ (mono-fluid) |
|---|---|---|
| −100 ± 10 | 0.085 | 0.377 |
| −100 ± 20 | 0.189 | 0.230 |
| −100 ± 30 | 0.147 | 0.172 |

TABLE 2

| Area (mm) | σ (two-fluids) | σ (mono-fluid) |
|---|---|---|
| −100 ± 10 | 0.250 | 0.598 |
| −100 ± 20 | 0.188 | 0.355 |
| −100 ± 30 | 0.145 | 0.265 |

From the data of Tables 1 and 2, it can be seen that the two-fluid process results in a wider radial width of the etching area and higher stability in etching amount between the substrates. In other words, the two-fluid process may be preferred if the process stability is important. However, this does not negate the use of the mono-fluid process. The mono-fluid process may be performed if narrower localized etching is desired.

In addition, the radial width of the etching area at a −100 mm position tends to be wider than that at a +100 mm position, and a variation in etching amount at that position also tends to be smaller. This is considered to be because the −100 mm position is closer to a position where the etching liquid is first applied, so that diffusion of the etching liquid has progressed more. Such a variation in etching results is inevitable as long as the first etching process is performed by fixing the nozzle and rotating the substrate once. However, the inventors believe that such a level of variation is not practically problematic. In addition, it is anticipated that the above variation is mitigated by arranging two nozzles at radially opposite positions at an equal distance from the center of the substrate and simultaneously initiating the discharge of the etching liquid from these two nozzles while rotating the substrate, for example, once.

### Fifth Embodiment of Etching Method

In the first to fourth embodiments above, the first etching process (localized etching process) and the second etching process (overall etching process) are performed as a series of processes but the present disclosure is not limited to this. A correction etching including the pre-wet process, the paddle-forming process, the first etching process, the rinse process and the drying process may be performed on a substrate (e.g., a dried substrate) that has undergone a conventional etching (including the second etching process but not including the first etching process).

Specifically, for example, the substrate that has undergone conventional etching is loaded into an inspection unit, where a known non-destructive inspection method such as spectroscopic ellipsometry is used to investigate the in-plane distribution of etching amount. If the in-plane distribution of etching amount does not meet the criteria, correction etching is performed on that substrate.

A database of a relationship between the inspection results (e.g., the in-plane distribution of etching amount) of the substrate that has undergone the conventional etching and conditions of the correction etching necessary to correct the distribution (non-uniform distribution) may be stored in the storage. In this case, the control device 4 that has received the inspection results may refer to the database to automatically determine the conditions of the correction etching.

Further, the correction etching may be performed on all substrates that have undergone the conventional etching in a first substrate processing apparatus under predetermined etching conditions in a second substrate processing apparatus. Further, if it is known that the etching amount distribution obtained by the conventional etching in the first substrate processing apparatus is stable and within a predetermined range, there may be no need to inspect the etching amount distribution of the substrate before performing the correction etching in the second substrate processing apparatus.

### Modifications of Second Etching Process

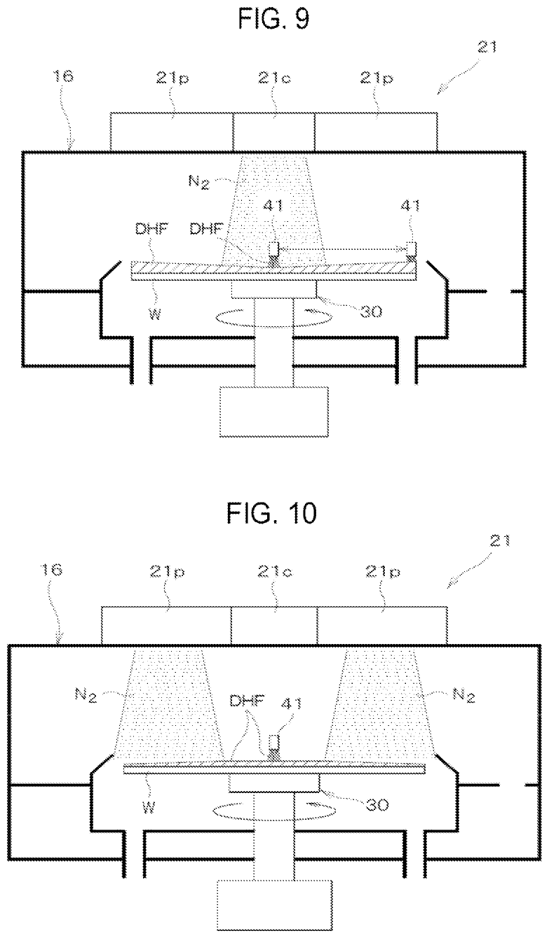

Next, modifications of the second etching process will be described with reference to FIGS. 9 and 10. The modifications of the second etching process described below may be used to adjust the etching amount distribution within the substrate plane in the second etching process of the etching method according to the first to fifth embodiments.

### First Modification

In a first modification, when performing the second etching process, as illustrated in FIG. 9, the DHIF nozzle 41, which discharges DHF, is reciprocated (also referred to as “scan”) between a space above the central portion of the substrate W and a space above the peripheral portion of the substrate W. Further, a low-humidity gas is discharged from a central outlet 21C of the FFU 21, so that the low-humidity gas is selectively sprayed onto the central portion of the substrate W. The low humidity gas may be any gas with a sufficiently lower humidity than the air in a clean room but may preferably be a gas with a humidity of 1% or less such as dry air or nitrogen gas. Clean air (air with the same humidity as the air in the clean room) may be discharged from a peripheral outlet 21P of the FFU 21.

The FFU configured to supply different gases (e.g., clean air and dry gas) to the central portion and the peripheral portion is well known in the art, and a detailed description of the structure is omitted.

The selective spraying of the low-humidity gas onto the central portion of the substrate W may be achieved by positioning a movable gas nozzle above the central portion of the substrate W and discharging the low-humidity gas from there toward the central portion of the substrate W.

According to this modification, by selectively spraying the low-humidity gas onto the central portion of the substrate W, evaporation of moisture in the DHF liquid film is promoted at the central portion of the substrate W, thereby resulting in an increase in the concentration of DHF. Further, by reciprocating the liquid application point of DHF on the surface of the substrate W from the DHF nozzle between the central portion and the peripheral portion of the substrate W, the liquid film of DHF present at the central portion of the substrate W becomes thinner while the DHF liquid application point is away from the central portion of the substrate W (compared to when the DHF liquid application point is fixed at the central portion of the substrate W). Therefore, the degree of increase in DHF concentration is greater in a case where the same amount of moisture evaporates. This allows for a greater etching rate at the central portion of the substrate W compared to the peripheral portion. This phenomenon may be used to adjust the etching amount distribution within the substrate plane.

### Second Modification

In a second modification, when performing the second etching process, the DHIF nozzle 41 is fixed above the central portion of the substrate W, as illustrated in FIG. 10. Further, a low-humidity gas is discharged from the peripheral outlet 21P of the FFU 21 toward the peripheral portion of the substrate W, so that the low-humidity gas is selectively sprayed onto the peripheral portion of the substrate W. Clean air (air with the same humidity as air in the clean room) is discharged from the central outlet 21C of the FFU 21.

In this case, the evaporation of moisture in the DHIF liquid film is promoted at the peripheral portion of the substrate W, thereby resulting in an increase in the concentration of DHIF. This allows for a greater etching rate at the peripheral portion of the substrate W compared to the central portion. This phenomenon may be used to adjust the etching amount distribution within the substrate plane.

The selective spraying of the low-humidity gas onto the peripheral portion of the substrate W may be achieved by positioning a movable gas nozzle above the peripheral portion of the substrate W and discharging the low-humidity gas from there toward the peripheral portion of the substrate W.

In addition, in both the first and second modifications, the etching rate may decrease due to the evaporation of moisture in a chemical liquid depending on the type or original concentration of the chemical liquid. In this case, it is possible to reduce the etching rate at the central portion (or peripheral portion) of the substrate W compared to the peripheral portion (or central portion).

The embodiments disclosed herein should be considered to be exemplary and not limitative in all respects. The above embodiments may be omitted, replaced or modified in various embodiments without departing from the scope of the appended claims and their gist.

The substrate as a processing target is not limited to a semiconductor wafer, but may be other types of substrates used in the manufacture of semiconductor devices, such as a glass substrate and a ceramic substrate.

1. A substrate processing method comprising:
a first etching process of performing etching, in a state where a paddle of a first process liquid is formed on an entire surface of a substrate, by locally discharging a second process liquid from a nozzle toward a target area locally set on the surface of the substrate, such that an etching rate in the target area differs from an etching rate in other areas; and
a second etching process of etching the entire surface of the substrate simultaneously by supplying an etching liquid so that the entire surface of the substrate is covered with a liquid film of the etching liquid while rotating the substrate,
wherein one of the first process liquid and the second process liquid used in the first etching process is the etching liquid, and the other is an etching inhibitor liquid that lowers an etching rate of the surface of the substrate by the etching liquid when mixed with the etching liquid.

2. The substrate processing method of claim 1, wherein the first etching process is performed in a state where rotation of the substrate is stopped.

3. The substrate processing method of claim 1, wherein the target area is a ring-shaped area concentric with a periphery of the substrate, and the first etching process includes rotating the substrate at least once while the nozzle fixed in position discharges the second process liquid.

4. The substrate processing method of claim 3, wherein when rotating the substrate in the first etching process, the substrate is rotated at a low speed that does break the paddle of the first process liquid.

5. The substrate processing method of claim 3, wherein a rotational speed of the substrate when rotating the substrate in the first etching process is equal to or less than 100 rpm.

6. The substrate processing method of claim 1, wherein during execution of the first etching process, the first process liquid is not supplied to the substrate in order to maintain the paddle of the first process liquid.

7. The substrate processing method of claim 1, wherein in the first etching process, the second process liquid is in a mist form and is discharged from the nozzle toward the target area in a two-fluid form mixed with a gas.

8. The substrate processing method of claim 1, further comprising:
acquiring an etching amount distribution in the surface of the substrate when the second etching process is performed without performing the first etching process; and
determining a process condition of the first etching process based on the etching amount distribution.

9. The substrate processing method of claim 8, wherein the process condition of the first etching process is determined to achieve a more uniform etching amount distribution when both the first etching process and the second etching process are performed, compared to when only the second etching process is performed.

10. The substrate processing method of claim 1, wherein the first process liquid is the etching inhibitor liquid, and the second process liquid is the etching liquid.

11. The substrate processing method of claim 1, wherein the first process liquid is the etching liquid, and the second process liquid is the etching inhibitor liquid.

12. The substrate processing method of claim 1, wherein the etching inhibitor liquid is deionized water (DIW), functional water, isopropyl alcohol (IPA), or a mixture thereof.

13. The substrate processing method of claim 1, wherein the first etching process is performed before the second etching process.

14. The substrate processing method of claim 1, wherein the second etching process is performed before the first etching process.

15. The substrate processing method of claim 1, wherein the second etching process is executed while spraying a low-humidity gas onto only one of a peripheral portion or a central portion of the substrate.

16. The substrate processing method of claim 15, wherein the second etching process is executed while moving a liquid application point of the etching liquid onto the substrate between the central portion and the peripheral portion of the substrate and spraying the low-humidity gas only onto the central portion of the substrate.

17. The substrate processing method of claim 15, wherein the second etching process is executed while maintaining a liquid application point of the etching liquid on the central portion of the substrate and spraying a dry gas only onto the peripheral portion of the substrate.

18. A substrate processing method comprising:
a localized etching process of performing etching, in a state where a paddle of a first process liquid is formed on an entire surface of a substrate, by locally discharging a second process liquid from a nozzle toward a target area locally set on the surface of the substrate, such that an etching rate in the target area differs from an etching rate in other areas,
wherein one of the first process liquid and the second process liquid is an etching liquid, and the other is an etching inhibitor liquid that lowers an etching rate of the surface of the substrate by the etching liquid when mixed with the etching liquid.

19. A substrate processing apparatus comprising:
a substrate holder that horizontally holds a substrate;
a rotation drive that rotates the substrate holder around a vertical axis;
a process fluid supply that supplies a process fluid to a surface of the substrate held by the substrate holder; and
a controller that controls the substrate holder, the rotation drive, and the process fluid supply to execute the substrate processing method of claim 1.

20. A substrate processing apparatus comprising:
a substrate holder that horizontally holds a substrate;
a rotation drive that rotates the substrate holder around a vertical axis;
a process fluid supply that supplies a process fluid to a surface of the substrate held by the substrate holder;
a gas supply configured to selectively spray a dry gas onto only one of a central portion and a peripheral portion of the surface of the substrate; and
a controller that controls the substrate holder, the rotation drive, the process fluid supply, and the gas supply to execute the substrate processing method of claim 15.
